(19) United States
(12) Patent Application Publication
(10) Pub. No.: US 2025/0191642 A1
(43) Pub. Date: Jun. 12, 2025

(54) Overlapping a Page Operation with a Processing-in-Memory Computation

(71) Applicant: Google LLC, Mountain View, CA (US)

(72) Inventors: Hongil Yoon, San Jose, CA (US); Inho Hwang, San Diego, CA (US); John Joseph, Kirkland, WA (US); Wenzhi Cui, Mountain View, CA (US); Benjamin Youngjae Cho, Mountain View, CA (US); Hee Jun Park, San Diego, CA (US)

(73) Assignee: Google LLC, Mountain View, CA (US)

(21) Appl. No.: 18/977,477

(22) Filed: Dec. 11, 2024

Related U.S. Application Data
(60) Provisional application No. 63/609,271, filed on Dec. 12, 2023.

(51) Int. Cl. G11C 11/4076; G11C 11/4093; G11C 11/4096

(52) U.S. Cl. CPC G11C 11/4076; G11C 11/4093; G11C 11/4096

(57) ABSTRACT

Techniques and apparatuses are described for overcoming memory, bandwidth, and/or power constraints in a processing-in-memory architecture. In example aspects, a memory device includes a logic circuit that is coupled to at least two banks. The memory device receives commands for concurrently performing at least a portion of a page operation and at least a portion of a processing-in-memory computation. The processing-in-memory computation is performed using the logic circuit and using data that was previously read from one of the active banks. The page operation is performed on another one of the banks that is idle to enable the logic circuit to access the data within this other bank for a later processing-in-memory computation. By performing the page operation during a same time as the processing-in-memory computation, a latency associated with the page operation can be effectively masked, thereby improving an overall efficiency of the memory device.

### RELATED APPLICATION(S)

This application claims the benefit of U.S. Provisional Patent Application Ser. No. 63/609,271, filed on Dec. 12, 2023, the disclosure of which is incorporated by reference herein in its entirety.

### BACKGROUND

With the emergence of artificial general intelligence (AGI) and generative artificial intelligence (GAI) technologies, computing devices can provide a wide range of services for a user. Many computing devices implement some form of artificial intelligence using a machine-learned model, such as a large-language model (LLM). As machine-learned models grow in size and complexity, there is an increased demand for designing computing devices that can quickly and efficiently execute machine-learned models.

### SUMMARY

Techniques and apparatuses are described for overlapping a page operation with a processing-in-memory computation. In example aspects, a memory device includes a logic circuit that is coupled to at least two banks. The memory device receives commands for concurrently performing at least a portion of a page operation and at least a portion of a processing-in-memory computation. The processing-in-memory computation is performed using the logic circuit and using data that was previously read from one of the active banks. The page operation is performed on another one of the banks that is idle to enable the logic circuit to access the data within this other bank for a later processing-in-memory computation. By performing the page operation during a same time as the processing-in-memory computation, a latency associated with the page operation can be effectively masked, thereby improving an overall efficiency of the memory device.

Aspects described below include a method performed by a memory device for overlapping a page operation with a processing-in-memory computation. The method includes performing, during a first time period and using a logic circuit that is coupled to at least two banks, a first processing-in-memory computation using first data that had been read from a first bank of the at least two banks. The method also includes performing, during the first time period, a page operation on a second bank of the at least two banks to enable the logic circuit to access second data that is stored within the second bank.

Aspects described below include a memory device capable of performing aspects of overlapping a page operation with a processing-in-memory computation. The memory device includes a memory array with at least two banks. The memory device also includes a logic circuit that is coupled to the at least two banks. The logic circuit is configured to perform, during a first time period, a first processing-in-memory computation using first data that had been read from a first bank of the at least two banks. The memory device additionally includes read and write circuitry configured to perform, during the first time period, a page operation on a second bank of the at least two banks to enable the logic circuit to access second data that is stored within the second bank.

Aspects described below include a method performed by a memory controller for overlapping a page operation and a processing-in-memory computation. The method includes transmitting, to a memory device capable of performing processing-in-memory, a processing-in-memory command to cause a logic circuit of the memory device to perform a first processing-in-memory computation using first data that had been read from a first bank of the memory device. The method also includes transmitting, to the memory device, a command to perform a page operation that enables the logic circuit to access second data that is stored in a second bank of the memory device. The transmitting of the processing-in-memory command and the transmitting of the command causes the memory device to concurrently perform at least a portion of the first processing-in-memory computation and at least a portion of the page operation during a first time period.

Aspects described below also include a system with means for overlapping a page operation with a processing-in-memory computation.

### BRIEF DESCRIPTION OF DRAWINGS

Apparatuses and techniques for overlapping a page operation with a processing-in-memory computation are described with reference to the following drawings. The same numbers are used throughout the drawings to reference like features and components:

FIG. 1 illustrates an example environment in which techniques for processing-in-memory can be implemented;

FIG. 2 illustrates an example implementation of a computing device with a memory device that can perform processing-in-memory;

FIG. 3 illustrates example communications between a host device and a memory device;

FIG. 4 illustrates example components of a memory device for transferring data to support processing-in-memory;

FIG. 5 illustrates an example relationship between multiple banks and a logic circuit of a memory device;

FIG. 6 illustrates example operations for performing aspects of overlapping a page operation with a processing-in-memory computation;

FIG. 7 illustrates an example scheme for performing aspects of overlapping a page operation with a processing-in-memory computation;

FIG. 8 illustrates an example method performed by a memory device for overlapping a page operation with a processing-in-memory computation;

FIG. 9 illustrates an example method performed by a memory controller for overlapping a page operation with a processing-in-memory computation; and

FIG. 10 illustrates an example computing system embodying, or in which techniques may be implemented for overlapping a page operation with a processing-in-memory computation.

### DETAILED DESCRIPTION

As machine-learned models grow in size and complexity, there is an increased demand for designing computing devices that can quickly and efficiently execute machine-learned models. Some computing devices utilize a technique known as processing-in-memory (PIM), which enables computing functions to be performed within a memory device, thereby reducing the amount of memory transfers that occur between the memory device and other components within the computing device. An example memory device with a processing-in-memory architecture includes a memory array for storing data associated with a machine-learned model and at least one logic circuit. The logic circuit is capable of performing computations that implement at least a portion of the machine-learned model and utilize data that is stored in the memory array. Overhead operations for accessing the data that is stored in the memory array can degrade an operating efficiency of the memory device for performing processing-in-memory. More specifically, computations performed by the logic unit can be inherently delayed while the memory device performs overhead operations.

To address this issue, techniques are described for overlapping a page operation with a processing-in-memory operation. In example aspects, a memory device includes a logic circuit that is coupled to at least two banks. The memory device receives commands for concurrently performing at least a portion of a page operation and at least a portion of a processing-in-memory computation. The processing-in-memory computation is performed using the logic circuit and using data that was previously read from one of the active banks. The page operation is performed on another one of the banks that is idle to enable the logic circuit to access the data within this other bank for a later processing-in-memory computation. By performing the page operation during a same time as the processing-in-memory computation, a latency associated with the page operation can be effectively masked, thereby improving an overall efficiency of the memory device.

### Operating Environment

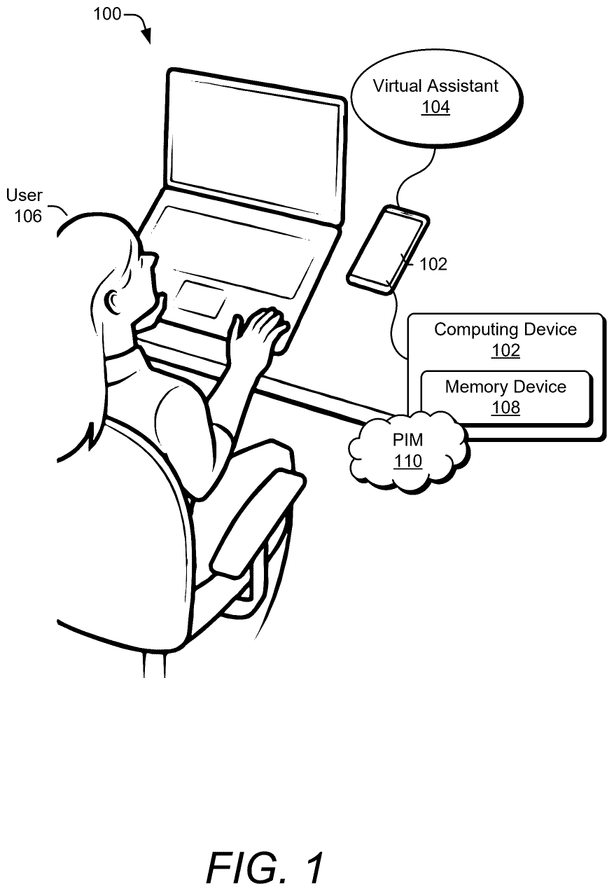

FIG. 1 is an illustration of an example environment 100 in which techniques utilizing processing-in-memory can be implemented. In the environment 100, a computing device 102 executes an application that provides a virtual assistant 104 (e.g., a voice-assistant service or a personal agent). Through voice commands, a user 106 can interact with the virtual assistant 104 to activate certain features of the computing device 102. In this manner, the virtual assistant 104 can provide hands-free control of the computing device 102. The virtual assistant 104 can also communicate information to the user 106 through the computing device 102's speakers and/or display.

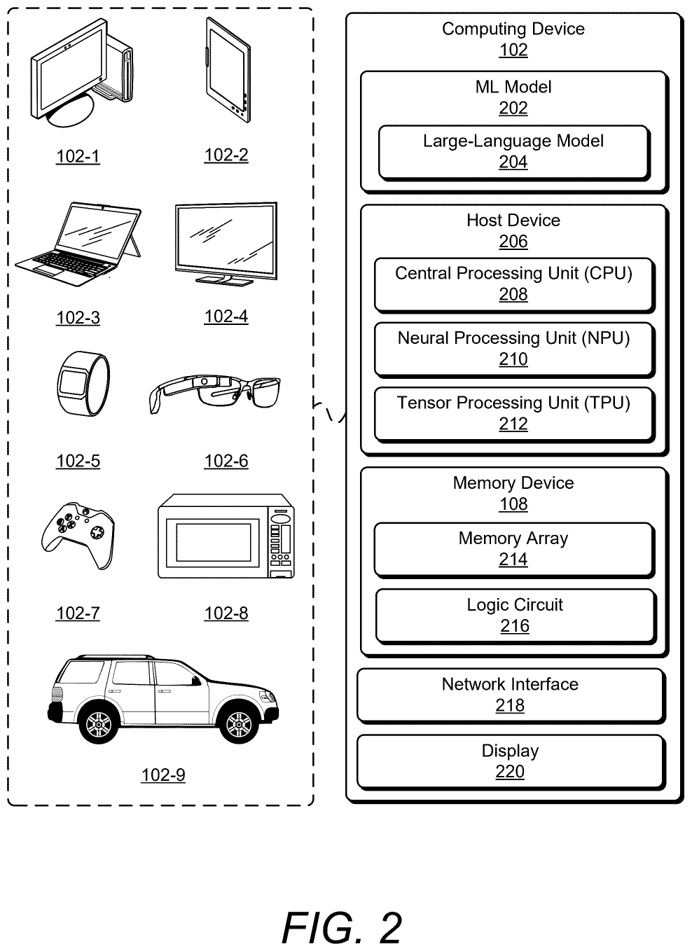

The virtual assistant 104 can be implemented using a machine-learned model, such as a large-language model. The computing device 102 includes a memory device 108 that supports processing-in-memory 110 (PIM 110) to implement at least a portion of the machine-learned model. The processing-in-memory 110 enables computing functions to be performed within the memory device 108, thereby reducing an amount of memory transfers that occur between the memory device 108 and another component with processing capabilities of the computing device 102 with processing capabilities. The computing device 102 is further described with respect to FIG. 2.

FIG. 2 illustrates an example computing device 102. The computing device 102 is illustrated with various non-limiting example devices including a desktop computer 102-1, a tablet 102-2, a laptop 102-3, a television 102-4, a computing watch 102-5, computing glasses 102-6, a gaming system 102-7, a microwave 102-8, and a vehicle 102-9. Other devices may also be used, such as a home service device, a smart speaker, a smart thermostat, a baby monitor, a Wi-Fi® router, a drone, a trackpad, a drawing pad, a netbook, an e-reader, a home automation and control system, a wall display, and another home appliance. Note that the computing device 102 can be wearable, non-wearable but mobile, or relatively immobile (e.g., desktops and appliances).

The computing device 102 is designed to provide one or more features associated with artificial intelligence (AI), such as the virtual assistant 104 of FIG. 1. To provide these features, the computing device 102 can implement a machine-learned model 202 (ML model 202). The machine-learned model 202 includes one or more neural networks. A neural network includes a group of connected nodes (e.g., neurons or perceptrons), which are organized into one or more layers. As an example, the machine-learned model 202 includes a deep neural network with an input layer, an output layer, and one or more hidden layers positioned between the input layer and the output layer. The nodes of the deep neural network can be partially-connected or fully-connected between the layers.

In some implementations, the neural network is a recurrent neural network (e.g., a long short-term memory (LSTM) neural network) with connections between nodes forming a cycle to retain information from a previous portion of an input data sequence for a subsequent portion of the input data sequence. In other cases, the neural network is a feed-forward neural network in which the connections between the nodes do not form a cycle. Additionally or alternatively, the machine-learned model 202 includes another type of neural network, such as a convolutional neural network. The machine-learned model 202 can also include one or more types of regression models and/or classification models. Example regression models include a single linear regression model, multiple linear regression models, logistic regression models, step-wise regression models, multi-variate adaptive regression splines, locally estimated scatterplot smoothing models. Example classification models include a binary classification model, a multi-class classification model, or a multi-label classification model.

In general, the machine-learned model 202 is trained using supervised or unsupervised learning to analyze data. The supervised learning can use simulated (e.g., synthetic) data or measured (e.g., real) data for training purposes. Outputs of the machine-learned model 202 can be passed to an application that is running on the computing device 102, can be passed to another component of the computing device 102, and/or can be presented by the computing device 102 to the user 106. In some implementations, the machine-learned model 202 is implemented as a large-language model (LLM) 204, such as LaMDA GLM, Chat GPT, Gopher, Chinchilla, Gemini, or PaLM.

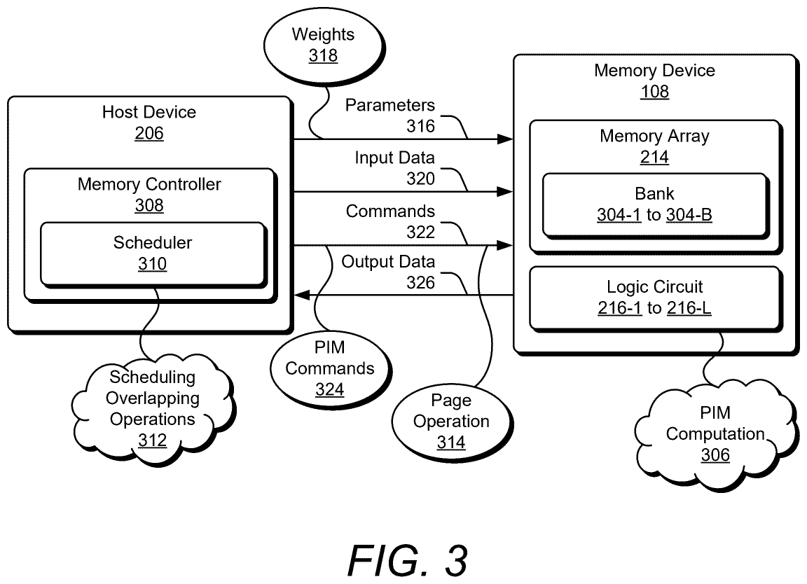

The computing device 102 includes at least one host device 206 and at least one memory device 108. The host device 206 can pass data to the memory device 108 for processing. This data can represent an input to the machine-learned model 202. The host device 206 can include at least one processor, at least one computer-readable storage medium, and a memory controller, which is further described with respect to FIG. 3. In example implementations, the host device 206 implements a central processing unit (CPU) 208, a neural processing unit (NPU) 210, a tensor processing unit (TPU) 212, or an artificial-intelligence accelerator. Other example implementations are also possible in which the host device 206 implements an image signal processor (ISP), a digital signal processor (DSP), a graphics processing unit (GPU), and the like. The host device 206 can be implemented on a system-on-chip (SoC).

The memory device 108, which can also be realized with a memory module, can include a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory or an auxiliary memory of the computing device 102.

The memory device 108 includes at least one memory array 214 and at least one logic circuit 216. The memory array 214 can include an array of memory cells, including but not limited to memory cells of DRAM, SDRAM, three-dimensional (3D) stacked DRAM, DDR memory, LPDDR SDRAM, and so forth. With the memory array 214, the memory device 108 can store various types of data that enable the memory device 108 to implement at least a portion of the machine-learned model 202. The logic circuit 216 performs aspects of processing-in-memory 110. The logic circuit 216 can also be referred to as a compute unit or a processing-in-memory computation unit. In general, the logic circuit 216 can perform some or all of the operations associated with running the machine-learned model 202. For example, the logic circuit 216 can perform multiplication operations, accumulation operations, and/or activation functions (e.g., a hyperbolic tangent (tanh) function, a rectified linear unit (ReLU) activation function, or a gaussian error linear unit (GeLU) activation function).

Computer engineers may implement the host device 206 and the various memories in multiple manners. In some cases, the host device 206 and the memory device 108 can be disposed on, or physically supported by, a printed circuit board (e.g., a rigid or flexible motherboard). The host device 206 and the memory device 108 may additionally be integrated together on an integrated circuit or fabricated on separate integrated circuits and packaged together. In the examples described herein, the memory device 108 implements at least a portion of the machine-learned model 202 using processing-in-memory 110. This means that the memory device 108 performs one or more operations associated with the machine-learned model 202. Various implementations are also possible in which the memory device 108 implements an entirety of the machine-learned model 202 or the memory device 108 and the host device 206 implement different portions of the machine-learned model 202.

The computing device 102 can also include a network interface 218 for communicating data over wired, wireless, or optical networks. For example, the network interface 218 may communicate data over a local-area-network (LAN), a wireless local-area-network (WLAN), a personal-area-network (PAN), a wide-area-network (WAN), an intranet, the Internet, a peer-to-peer network, point-to-point network, a mesh network, Bluetooth®, and the like. The computing device 102 may also include the display 220. The host device 206 and the memory device 108 are further described with respect to FIG. 3.

FIG. 3 illustrates example communications between the host device 206 and the memory device 108. In the depicted configuration, the memory device 108 includes the memory array 214, logic circuits 216-1 to 216-L, and an interface 302. The variable L represents a positive integer that is less than B. Using the memory array 214, the memory device 108 stores information for implementing at least a portion of the machine-learned model 202. The memory array 214 can include at least two banks 304-1 to 304-B, where B represents a positive integer. The multiple banks 304 can be organized in different bank groups, different ranks, and/or different channels. The quantity of banks 304 (e.g., the variable B) can vary depending on a design of the memory device 108. In example implementations, the quantity of banks 304 is equal to a power of two, such as 8, 16, 32, or 64.

Each logic circuit 216-1 to 216-L is coupled to at least two of the banks 304-1 to 304-B. In various implementations, a logic circuit 216 can be coupled to two banks 304, three banks 304, four banks 304, and so forth. The logic circuit 216 performs a processing-in-memory computation 306 using data that is stored in the corresponding banks 304. For example, the logic circuit 216 performs multiplication operations, accumulation operations, and/or activation functions to implement at least a portion of the machine-learned model 202.

The host device 206 includes at least one memory controller 308. The memory controller 308 provides a high-level or logical interface between a processor of the host device 206 (not shown) and the memory device 108. The memory controller 308 can be realized with any of a variety of suitable memory controllers (e.g., a double-data-rate (DDR) memory controller 306 that can process requests for data stored on the memory device 108). Although not explicitly shown, the host device 206 can include a physical interface (PHY) that transfers data between the memory controller 308 and the memory device 108 through an interconnect.

The memory controller 308 implements a scheduler 310 capable of scheduling overlapping operations 312. In particular, the scheduler 312 generates commands that enable a logic circuit 216 to perform processing-in-memory computations 306 concurrently while the memory device 108 performs a page operation 314. The scheduler 312 has access to information about a duration of a processing-in-memory computation 306 and a duration of a page operation 314. With this information, the scheduler 312 can cause the memory controller 308 to transmit commands that initiate the processing-in-memory computation 306 and initiate the page operation 314 to cause both operations to occur concurrently (e.g., overlap in time). In this way, the scheduler 310 can effectively mask a latency associated with the page operation 314 and improve an overall efficiency of the memory device 108 for performing processing-in-memory 110.

During initialization, the host device 206 transmits parameters 316 to the memory device 108. The parameters 316 specify characteristics of the machine-learned model 202, which can include weights 318, biases, kernel sizes or parameters, activation functions, and stride/pooling configurations. The parameters 316 can also identify nodes that are utilized or layers that are skipped. The memory device 108 stores the weights 318 in the memory array 214. Other implementations are also possible in which the memory device 108 is pre-programmed with the weights 318 in a different manner.

During normal operations, the memory controller 306 of the host device 206 transmits input data 320 and commands 322 to the memory device 108. The commands 322 can instruct the memory device 108 to perform read and/or write operations and generally enable the memory device 108 to appropriately use the parameters 316 and the input data 320 to perform operations of the machine-learned model 202. A first example command 322 includes a command for performing a page operation 314. An example page operation 314 can include a page open operation, which involves activating a row of a bank 304. Another example page operation 314 includes a page close operation, which involves precharging a row of the bank 304. The commands 322 can also include instructions specific for the logic circuit 216 to perform the processing-in-memory computation 306. These instructions are referred to as PIM commands 324.

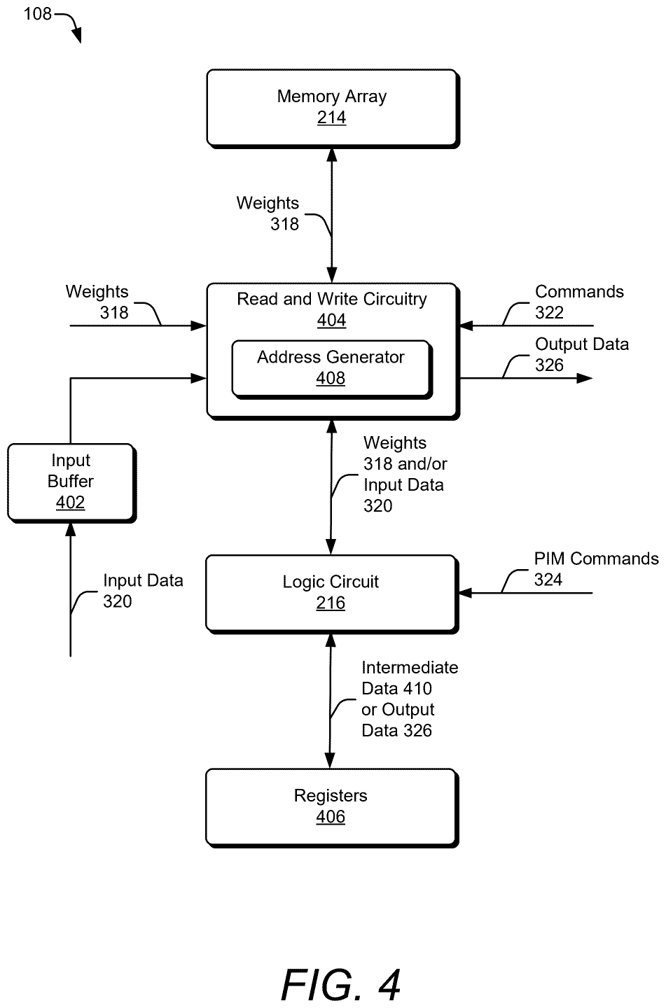

Based on the commands 322, the logic circuit 216 processes the input data 320 and the weights 318 to generate output data 326. The memory device 108 transmits the output data 326 to the host device 206. The host device 206 can pass the output data 326 to an application or present the output data 326 to the user 106. The propagation of information within the memory device 108 for performing processing-in-memory 110 is further described with respect to FIG. 4.

FIG. 4 illustrates example components of the memory device 108 and the propagation of information between these components. In the depicted configuration, the memory device 108 includes at least one input buffer 402, the memory array 214, read and write circuitry 404, the logic circuit 216, and multiple registers 406. Although a single logic circuit 216 is depicted in FIG. 4 for simplicity, the memory device 108 can include multiple logic circuits 216, as described with respect to FIG. 3.

The input buffer 402 provides temporary storage of the input data 320. The input buffer 402 can be implemented using one or more buffers, a queue, cache memory, or multiple registers. In general, the input buffer 402 temporarily stores the input data 320 prior to the input data 320 being passed to the logic circuit 216.

The read and write circuitry 404 is coupled to the input buffer 402, the memory array 214, and the logic circuit 216. In general, the read and write circuitry 404 enables the appropriate information to be passed between the input buffer 402, the memory array 214, the logic circuit 216, the registers 406, and the host device 206, as further described below. The read and write circuitry 404 can include an address generator 408, which identifies appropriate addresses that are to be accessed in the memory array 214 to support processing-in-memory 110.

The registers 406 are coupled to the logic circuit 216 and provide temporary storage for data while the logic circuit 216 performs processing-in-memory 110. A first example type of data can include intermediate data 410 generated by the logic circuit 216 during normal operations. The registers 406 can pass the intermediate data 410 back to the logic circuit 216 for further processing at a later time. A second example type of data can include the output data 326, which is eventually transferred to the host device 206.

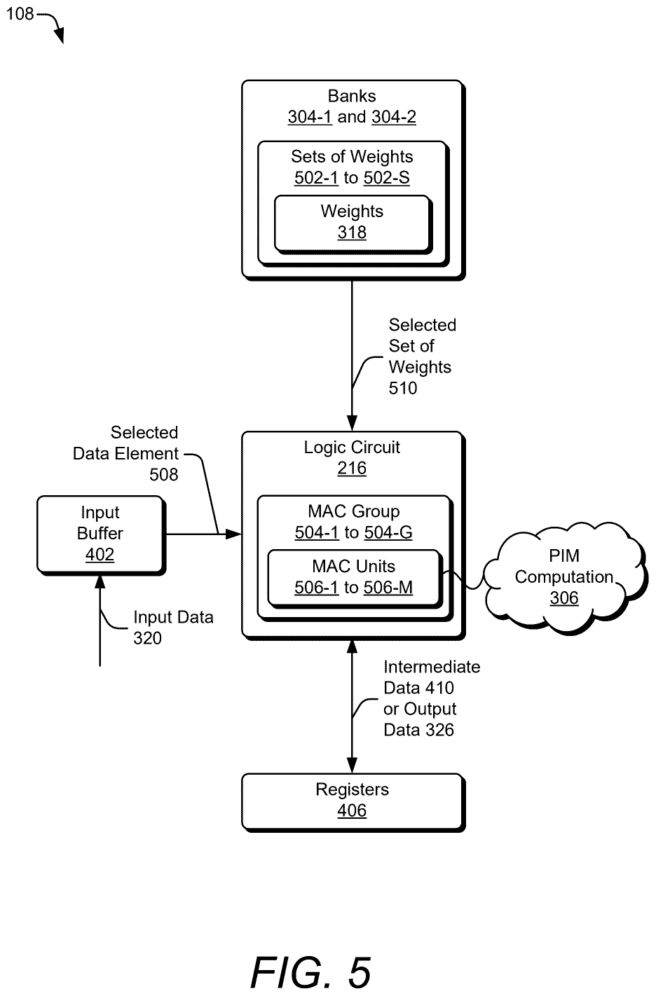

During initialization, the read and write circuitry 404 can write the weights 318 to the memory array 214. During normal operations, the input buffer 402 stores the input data 320 that is transferred from the host device 206. The read and write circuitry 404 can read the weights 318 from the memory array 214, transfer the weights 318 to the logic circuit 216, and transfer the input data 320 from the input buffer 402 to the logic circuit 216 based on the commands 322. The logic circuit 216 performs processing-in-memory computations 306 based on the PIM commands 324 and using the data that is provided by the read and write circuitry 404 and/or the registers 406. Once the logic circuit 216 generates the output data 326, the read and write circuitry 404 enables the output data 326 to be transferred to the host device 206. Other operations of the memory device 108 for overlapping a page operation 314 with a processing-in-memory computation 306 are further described with respect to FIG. 5.

FIG. 5 illustrates an example relationship between multiple banks 304 and a logic circuit 216 of the memory device 108. In the depicted configuration, the memory device 108 includes a logic circuit 216 that is coupled to two banks 304-1 and 304-2. The banks 304-1 and 304-2 can be coupled to the logic circuit 216 via the read/write circuitry 404 of FIG. 4. Other implementations are also possible in which the logic circuit 216 is coupled to more than two banks 304.

Each of the banks 304 can store multiple sets of weights 502-1 to 502-S, where S represents a positive integer that is greater than one. In an example implementation, each set of weights 502 can be used to process one element of the input data 320. Each set of weights 502 can be stored in at least a portion of a row within the bank 304. The quantity of weights 318 associated with a given set of weights 502 can vary depending on a quantity of bits associated with each weight 318, a design of the memory device 108, and/or a design of the machine-learned model 202. In example implementations, each set of weights 502 includes a quantity of weights that is equal to a power of two (e.g., 16, 32, 64, 128, or 256).

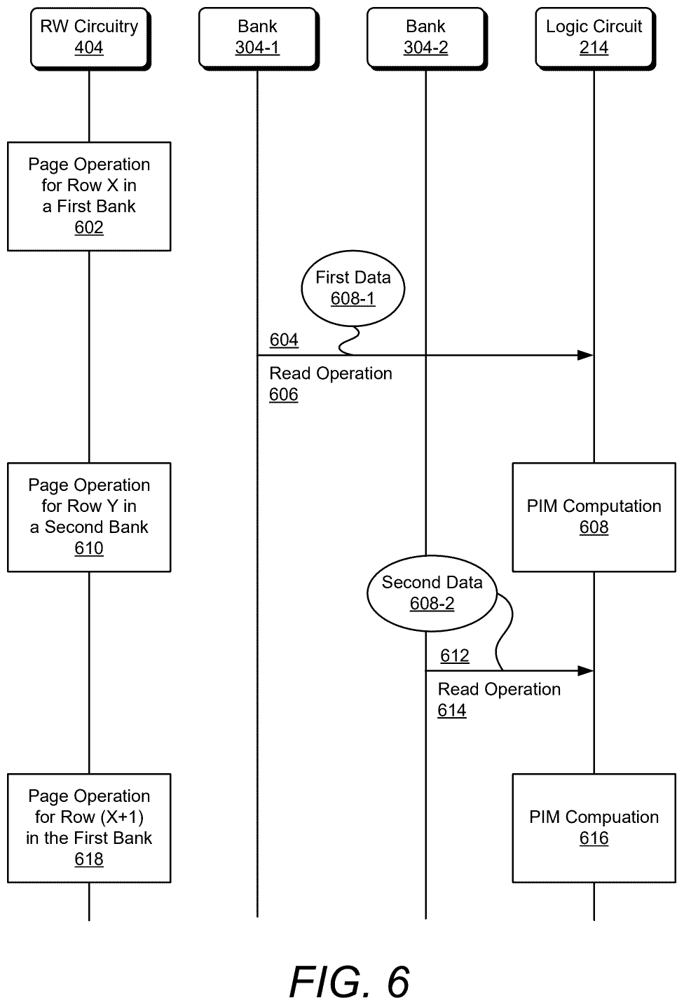

Each of the banks 304 can selectively be an active state or an idle state. While in the active state, information that is stored within the banks 304 can be read using the read and write circuitry 404 and transferred to an appropriate destination, such as the logic circuit 216. During the idle state, the read and write circuitry 404 can perform the page operation 314 to prepare the bank 304 for a subsequent read operation, which is performed when the bank 304 is active. By causing one of the banks 304 to be in the active state and the remaining banks 304 to be in the idle state, the memory device 108 can perform aspects of overlapping the page operation 314 with a processing-in-memory computation 306, as further described with respect to FIG. 6.

The logic circuit 216 includes multiplication-accumulation (MAC) groups 504-1 to 504-G (MAC groups 504-1 to 504-G), where G represents a positive integer. Although not explicitly shown in FIG. 5, the logic circuit 216 can also include other components, such as a bias circuit and an activation circuit. The bias circuit can apply a bias to data that is generated by the MAC group 504. The activation circuit can perform an activation function to the data that is generated by the MAC Group 504.

Each MAC group 504 includes multiple MAC units 506-1 to 506-M, where M represents a positive integer. In example implementations, the quantity of MAC units 506 (e.g., a value of variable M) is equal to a power of two, such as 16, 32, 64, or 128. In general, the quantity of MAC units 506 can vary depending on a design of the memory device 108 and a design of the machine-learned model 202. Each MAC unit 506 can perform the processing-in-memory computation 306 to implement a portion of the machine-learned model 202.

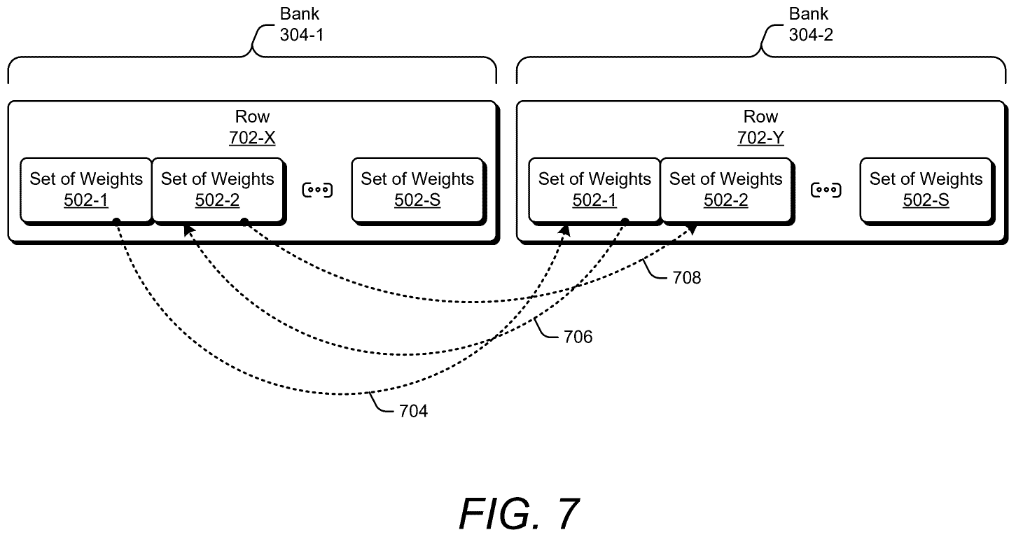

During initialization, the weights 318 are stored within the banks 304. During normal operations, a selected data element 508 is transferred from the input buffer 402 to the logic circuit 216. More specifically, the selected data element 508 is broadcasted over a bus to the MAC units 506. A selected set of weights 510 is read from one of the banks 304 and is transferred to the logic circuit 216 via the read and write circuitry 404. As such, each MAC unit 506 receives one of the weights 318 within the selected set of weights 510. The MAC units 506 of the logic circuit 216 process the selected data element 508 using the selected set of weights 510. In some cases, the MAC units 506 generate the intermediate data 410 or the output data 326, which can be temporarily stored within the registers 406. To mask the latency associated with the page operation 314, the scheduler 310 of the memory controller 308 causes the memory device 108 to perform a page operation 314 during a same time interval that the logic circuit 216 performs a processing-in-memory computation 306, as further described with respect to FIGS. 6 and 7.

Overlapping a Page Operation with a Processing-In-Memory Computation

FIG. 6 illustrates example operations for performing aspects of overlapping a page operation with a processing-in-memory computation. At 602, the read and write circuitry 404 performs a first page operation 314 for row X in the first bank 304-1. At this time, the first bank 304-1 and the second bank 304-2 can be in an idle state. The page operation 314 can include generating internal commands and identifying an address for activating row X in the first bank 304-1. As the first bank 304-1 is in the idle state, row X may not be formally activated until 604.

At 604, the first bank 304-1 is in the active state and the second bank 304-2 is in the idle state. The read and write circuitry 404 performs a first read operation 606. In particular, the read and write circuitry 404 activates row X based on the internal commands generated at 602. The read and write circuitry 404 reads first data 608-1 from row X of the first bank 304-1 and transfers the first data 608-1 to the logic circuit 216. The first data 608-1 can include a first selected set of weights 510.

At 608, the logic circuit 216 performs a first processing-in-memory computation 306 using the first data 608-1. For example, at least one of the MAC units 506 performs a multiplication operation and/or an accumulation operation using a weight 318 associated with the first data 608-1. During a same time that the first processing-in-memory computation 306 occurs, the read and write circuitry 404 performs a second page operation 314 for row Y in the second bank 304-2, as indicated at 610. The second page operation 314 can include generating internal commands and identifying an address for activating row Y in the second bank 304-2. At this time, the second bank 304-2 is in the idle state. As such, row Y may not be formally activated until 608.

At 612, the second bank 304-2 is in the active state and the first bank 304-1 is in the idle state. The read and write circuitry 404 performs a second read operation 614. In particular, the read and write circuitry 404 activates row Y based on the internal commands generated at 610. The read and write circuitry 404 reads second data 608-2 from row Y of the second bank 304-2 and transfers the second data 608-2 to the logic circuit 216. The second data 608-2 can include a second selected set of weights 510.

At 616, the logic circuit performs a second processing-in-memory computation 306 using the second data 608-2. For example, at least one of the MAC units 506 performs a multiplication operation and/or an accumulation operation using a weight 318 associated with the second data 608-2. During a same time that the second processing-in-memory computation 306 occurs, the read and write circuitry 404 performs a third page operation 314 for row (X+1) in the first bank 304-1, as indicated at 618. At this time, the first bank 304-1 is in the idle state.

By performing the second and third page operations 314 during a same time that the first and second processing-in-memory computations 306 are performed, the memory device 108 can operate at a higher level of efficiency compared to other memory devices that perform these operations in series. Although the example described above is with respect to two banks 304, the techniques for overlapping a page operation 314 with a processing-in-memory computation 306 can generally be applied to two or more banks 304 that are coupled to the logic circuit 216.

In the above example, the page operation 314 is described with respect to performing a page open operation, which involves activating a specified row. Other page operations 314 can also be performed concurrently with the processing-in-memory computation 306, including a page close operation. The page close operation involves precharging a specified row. The banks 304-1 and 304-2 can be accessed in an alternating pattern to facilitate the overlapping of multiple page operations 314 with multiple processing-in-memory computations 306, as further described with respect to FIG. 7.

FIG. 7 illustrates an example scheme for performing aspects of overlapping a page operation 314 with a processing-in-memory computation 306. In the depicted example, the banks 304-1 and 304-2 are shown to include rows 702-X and 702-Y, respectively. The variables X and Y represent positive integers and may or may not be equal to each other. The banks 304-1 and 304-2 are alternatively accessed by the logic circuit 216. In this example, the bank 304-1 is activated first and a first set of weights 502-1 of the first bank 304-1 is read and transferred to the logic circuit 216. As indicated at 704, the memory device 108 then switches to activating the second bank 304-2 and causing the first bank 304-1 to be in the idle state. A first set of weights 502-1 of the second bank 304-2 is read and transferred to the logic circuit 216.

At 706, the memory device 108 switches to accessing the first bank 304-1 and causing the second bank 304-2 to be in the idle state. Since the row 702-X of the first bank 304-1 was previously activated, the read and write circuitry 404 can directly proceed to reading and transferring a second set of weights 502-2 of the first bank 304-1 to the logic circuit 216 without performing a page operation 314. At 708, the memory device 108 switches to accessing the second bank 304-2 and causing the first bank 304-1 to be in the idle state. A second set of weights 502-2 of the second bank 304-2 is read and transferred to the logic circuit 216.

In some cases, the row 702-X and the row 702-Y can represent a same row within the corresponding banks 304-1 and 304-2. For example, the row 702-X and the row 702-Y can respectively represent a first row in the bank 304-1 and a first row in the bank 304-2. Other cases are also possible in which the rows 702-X and 702-Y represent different rows within the corresponding banks 304-1 and 304-2. For example, the row 702-X can represent a first row in the bank 304-1 and the row 702-Y can represent a second row in the bank 304-2. By alternating between reading sets of weights 502 between the two banks 304-1 and 304-2, the memory device 108 can concurrently perform the page operation 314 with the processing-in-memory computation 306 to improve an operating efficiency of the memory device 108.

In other cases, the sets of weights 502-1 to 502-S can be stored in different rows 702 for each bank 304. In this case, an entirety of the columns within a row 702 of a bank 304 can be read prior to switching to reading an entirety of the columns within a row 702 of another bank 304. In this way, the page operations 314 for accessing different sets of weights 502 can be readily overlapped with the processing-in-memory computations 306 as the memory device 108 switches between reading a set of weights 502 within the first bank 304-1 and reading a set of weights 502 within the second bank 304-2.

### Example Methods

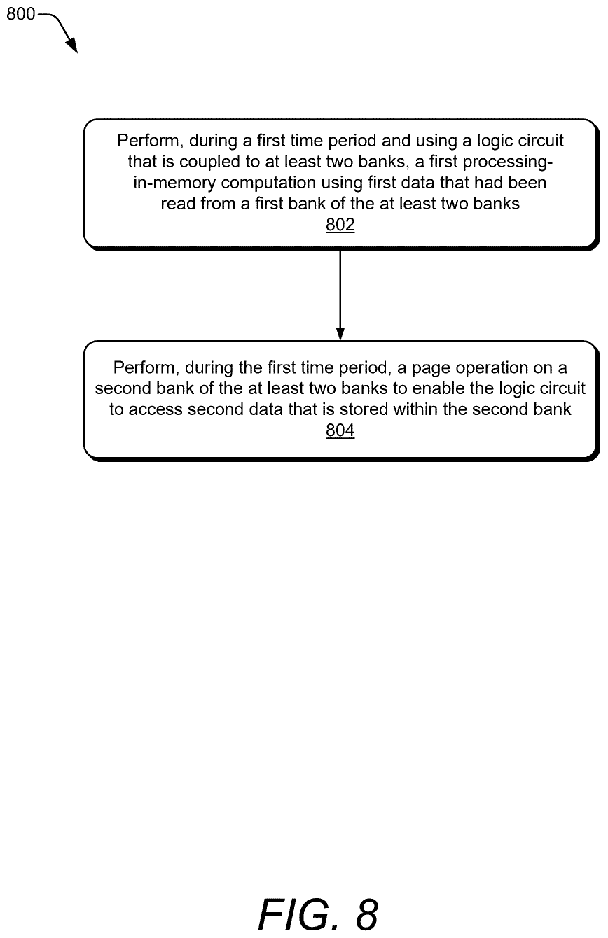

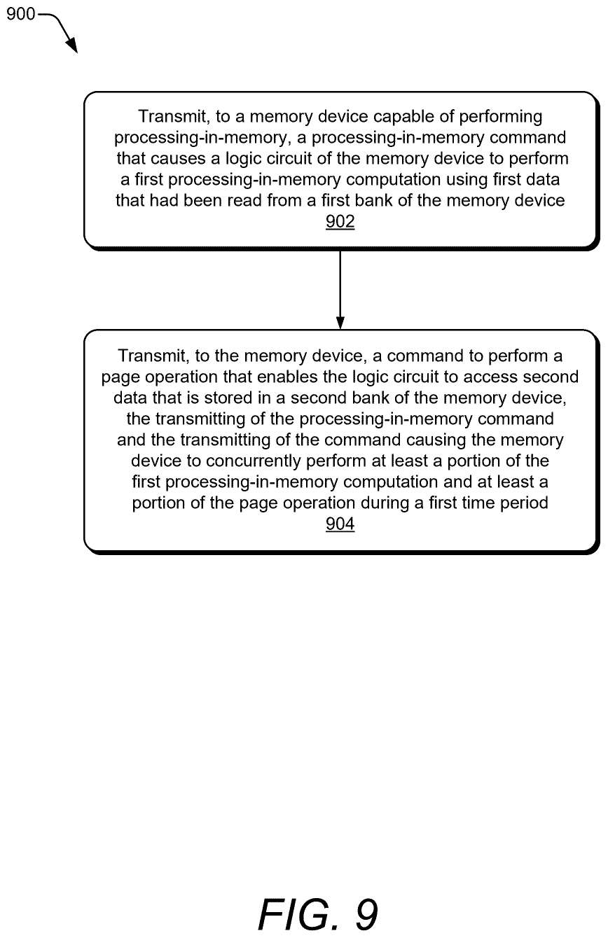

FIGS. 8 and 9 depict example methods 800 and 900 for implementing aspects of overcoming memory, bandwidth, and/or power constraints in a processing-in-memory architecture. Methods 800 to 900 are shown as sets of operations (or acts) performed but not necessarily limited to the order or combinations in which the operations are shown herein. Further, any of one or more of the operations may be repeated, combined, reorganized, or linked to provide a wide array of additional and/or alternate methods. In portions of the following discussion, reference may be made to the environment 100 of FIG. 1, and entities detailed in FIGS. 2 to 5, reference to which is made for example only. The techniques are not limited to performance by one entity or multiple entities operating on one device.

At 802 in FIG. 8, a first processing-in-memory computation is performed using first data that had been read from a first bank of the at least two banks. The performing of the first processing-in-memory computation occurring during a first time period and using a logic circuit that is coupled to at least two banks. For example, the logic circuit 216 performs a first processing-in-memory computation 306 using first data that had been read from a first bank 304-1. The first data can include a first selected set of weights 510. The first processing-in-memory computation 306 occurs during a first time period.

At 804, a page operation is performed, during the first time period, on a second bank of the at least two banks to enable the logic circuit to access second data that is stored within the second bank. For example, the read and write circuitry 404 performs a page operation 314 on a second bank 304-2 during the first time period. The page operation 314 enables the logic circuit 216 to access second data that is stored within the second bank 304-2. For example, the page operation 314 can include a page open operation, which causes a row within the second bank 304-2 to be activated. This enables the logic circuit 216 to access the second data, which can include a second selected set of weights 510, for performing a second processing-in-memory computation 306, as shown in FIG. 6.

At 902 in FIG. 9, a processing-in-memory command that causes a logic circuit of a memory device to perform a first processing-in-memory computation is transmitted. The first processing-in-memory computation uses first data that had been read from a first bank of the memory device. For example, the memory controller 308 transmits the processing-in-memory command 324 to cause the logic circuit 216 of the memory device 108 to perform a first processing-in-memory computation 306 using first data that had been read from a first bank 304-1 of the memory device 108. The first data can include a first selected set of weights 510.

At 904, a command to perform a page operation that enables the logic circuit to access second data that is stored in a second bank of the memory device is transmitted to the memory device. The transmitting of the processing-in-memory command and the transmitting of the command causes the memory device to concurrently perform at least a portion of the first processing-in-memory computation and at least a portion of the page operation during a first time period. For example, the memory controller 308 transmits a command 322 to cause the memory device 108 to perform a page operation 314 that enables the logic circuit 216 to access second data that is stored in the second bank 304-2. The page operation 314 can involve activating a row within the second bank 304-2 that stores the second data. The second data can include a second selected set of weights 510. The transmitting of the processing-in-memory command 324 and the transmitting of the command 322 cause the memory device 108 to concurrently perform at least a portion of the first processing-in-memory computation 306 and at least a portion of the page operation 314 during a first time period. In this way, a latency associated with the page operation 314 can be effectively masked to improve an overall efficiency of the memory device 108 for performing processing-in-memory 110.

### Example Computing System

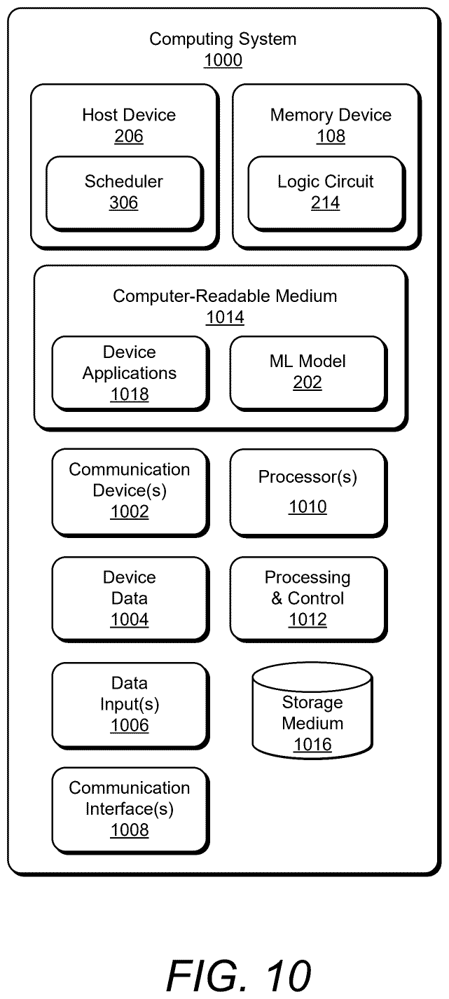

FIG. 10 illustrates various components of an example computing system 1000 that can be implemented as any type of client, server, and/or computing device as described with reference to the previous FIGS. 2 and 3 to implement aspects overlapping a page operation with a processing-in-memory computation.

The computing system 1000 includes communication devices 1002 that enable wired and/or wireless communication of device data 1004 (e.g., received data, data that is being received, data scheduled for broadcast, or data packets of the data). The device data 1004 or other device content can include configuration settings of the device, media content stored on the device, and/or information associated with a user of the device. Media content stored on the computing system 1000 can include any type of audio, video, and/or image data. The computing system 1000 includes one or more data inputs 1006 via which any type of data, media content, and/or inputs can be received, such as human utterances, user-selectable inputs (explicit or implicit), messages, music, television media content, recorded video content, sensor data (e.g., radar data or ultrasound data), and any other type of audio, video, and/or image data received from any content and/or data source.

The computing system 1000 also includes communication interfaces 1008, which can be implemented as any one or more of a serial and/or parallel interface, a wireless interface, any type of network interface, a modem, and as any other type of communication interface. The communication interfaces 1008 provide a connection and/or communication links between the computing system 1000 and a communication network by which other electronic, computing, and communication devices communicate data with the computing system 1000.

The computing system 1000 includes one or more processors 1010 (e.g., any of microprocessors, controllers, and the like), which process various computer-executable instructions to control the operation of the computing system 1000. Alternatively or in addition, the computing system 1000 can be implemented with any one or combination of hardware, firmware, or fixed logic circuitry that is implemented in connection with processing and control circuits which are generally identified at 1012. Although not shown, the computing system 1000 can include a system bus or data transfer system that couples the various components within the device. A system bus can include any one or combination of different bus structures, such as a memory bus or memory controller, a peripheral bus, a universal serial bus, and/or a processor or local bus that utilizes any of a variety of bus architectures.

The computing system 1000 also includes a computer-readable medium 1014, such as one or more memory devices that enable persistent and/or non-transitory data storage (i.e., in contrast to mere signal transmission), examples of which include random access memory (RAM), non-volatile memory (e.g., any one or more of a read-only memory (ROM), flash memory, EPROM, EEPROM, etc.), and a disk storage device. The disk storage device may be implemented as any type of magnetic or optical storage device, such as a hard disk drive, a recordable and/or rewriteable compact disc (CD), any type of a digital versatile disc (DVD), and the like. The computing system 1000 can also include a mass storage medium device (storage medium) 1016.

The computer-readable medium 1014 provides data storage mechanisms to store the device data 1004, as well as various device applications 1018 and any other types of information and/or data related to operational aspects of the computing system 1000. For example, an operating system 1020 can be maintained as a computer application with the computer-readable medium 1014 and executed on the processors 1010. The device applications 1018 may include a device manager, such as any form of a control application, software application, signal-processing and control module, code that is native to a particular device, a hardware abstraction layer for a particular device, and so on.

In this example, the computer-readable medium 1014 can store information associated with the machine-learned model 202 of FIG. 2. The processor 1010 and/or the computer-readable medium 1014 can implement the host device 206 of FIG. 2. The computing system 1000 also includes at least one host device 206 and at least one memory device 108. In some implementations, the processor 1010 and/or the computer-readable medium 1014 implement the host device 206. The host device 206 includes the scheduler 310, which can generate commands that cause the memory device 108 to overlap a page operation 314 with a processing-in-memory computation 306.

The memory device 108 includes the logic circuit 216 capable of performing the processing-in-memory computation 306 to implement at least a portion of the machine-learned model 202. The memory device 108 also includes any system components, engines, managers, software, firmware, and/or hardware to implement techniques for performing at least a portion of the page operation 314 with at least a portion of a processing-in-memory computation 306.

### CONCLUSION

Although techniques for overlapping a page operation with a processing-in-memory computation have been described in language specific to features and/or methods, it is to be understood that the subject of the appended examples is not necessarily limited to the specific features or methods described. Rather, the specific features and methods are disclosed as example implementations of overlapping a page operation with a processing-in-memory computation.

Some Examples are described below.

Example 1: A method performed by a memory device, the method comprising:
performing, during a first time period and using a logic circuit that is coupled to at least two banks, a first processing-in-memory computation using first data that had been read from a first bank of the at least two banks; and
performing, during the first time period, a page operation on a second bank of the at least two banks to enable the logic circuit to access second data that is stored within the second bank.

Example 2: The method of example 1, wherein:
the performing of the first processing-in-memory computation comprises receiving, from a memory controller of a host device, a processing-in-memory command that instructs the logic circuit to perform the first processing-in-memory computation;
the performing of the page operation comprises receiving, from the memory controller, a command that instructs the memory device to perform the page operation; and
a timing associated with the receiving of the processing-in-memory command and a timing associated with the receiving of the command causes the memory device to concurrently perform at least a portion of the first processing-in-memory computation and at least a portion of the page operation.

Example 3: The method of example 1 or 2, further comprising:
performing, during a second time period and using the logic circuit, a second processing-in-memory computation using the second data; and
performing, during the second time period, another page operation on the first bank to enable the logic circuit to access third data that is stored within the first bank.

Example 4: The method of example 3, wherein:
the page operation comprises a second page operation;
the other page operation comprises a third page operation; and
the method further comprises performing, prior to the first time period, a first page operation on the first bank to enable the logic circuit to access the first data.

Example 5: The method of example 4, wherein:
the performing of the first page operation on the first bank comprises activating a first row of the first bank that stores the first data; and
the performing of the second page operation on the second bank comprises activating a second row of the second bank that stores the second data.

Example 6: The method of example 5, wherein the first row and the second row comprise a same row of a corresponding bank.

Example 7: The method of example 5 or 6, wherein the performing of the third page operation on the first bank comprises:
precharging the first row of the first bank that stores the first data; and
activating a third row of the first bank that stores the third data.

Example 8: The method of any previous example, wherein:
the first data and the second data comprise different sets of weights of a machine-learned model; and
the performing of the first processing-in-memory computation comprises performing, using a weight of the machine-learned model, at least one of a multiplication operation or an accumulation operation to implement a portion of the machine-learned model.

Example 9: A memory device comprising:
a memory array comprising at least two banks;
a logic circuit coupled to the at least two banks and configured to perform, during a first time period, a first processing-in-memory computation using first data that had been read from a first bank of the at least two banks; and
read and write circuitry configured to perform, during the first time period, a page operation on a second bank of the at least two banks to enable the logic circuit to access second data that is stored within the second bank.

Example 10: The memory device of example 9, wherein:
the first bank is configured to be in an active state during the first time period; and
the second bank is configured to be in an idle state during the first time period.

Example 11: The memory device of example 10, wherein:
the logic circuit is configured to perform, during a second time period, a second processing-in-memory computation using the second data; and
the read and write circuitry is configured to perform, during the second time period, another page operation on the first bank to enable the logic circuit to access third data that is stored within the first bank.

Example 12: The memory device of example 11, wherein:
the first bank is configured to be in the idle state during the second time period; and
the second bank is configured to be in the active state during the first time period.

Example 13: The memory device of any one of examples 9 to 12, wherein:
the page operation comprises a second page operation;
the other page operation comprises a third page operation; and
the read and write circuitry is configured to perform, prior to the first time period, a first page operation on the first bank to enable the logic circuit to access the first data.

Example 14: The memory device of any one of examples 9 to 13, wherein:
the first data and the second data comprise different sets of weights of a machine-learned model; and
the logic circuit is configured to perform, using a weight of the machine-learned model, at least one of a multiplication operation or an accumulation operation to implement a portion of the machine-learned model.

Example 15: A method performed by a memory controller, the method comprising:
transmitting, to a memory device capable of performing processing-in-memory, a processing-in-memory command to cause a logic circuit of the memory device to perform a first processing-in-memory computation using first data that had been read from a first bank of the memory device; and
transmitting, to the memory device, a command to perform a page operation that enables the logic circuit to access second data that is stored in a second bank of the memory device, the transmitting of the processing-in-memory command and the transmitting of the command causing the memory device to concurrently perform at least a portion of the first processing-in-memory computation and at least a portion of the page operation during a first time period.

Example 16: The method of example 15, wherein:
the first data and the second data comprise different sets of weights of a machine-learned model; and
the transmitting of the processing-in-memory command causes the logic circuit to perform, using a weight of the machine-learned model, at least one of a multiplication operation or an accumulation operation to implement a portion of the machine-learned model.

Example 17: The method of example 15 or 16, further comprising:
transmitting, to the memory device, a second processing-in-memory command to cause the logic circuit to perform a second processing-in-memory computation using the second data; and
transmitting, to the memory device, a second command to perform another page operation that enables the logic circuit to access third data that is stored in the first bank of the memory device, the transmitting of the second processing-in-memory command and the transmitting of the second command causing the memory device to concurrently perform at least a portion of the second processing-in-memory computation and at least a portion of the other page operation during a second time period.

Example 18: The method of example 17, wherein:
the command comprises a second command;
the page operation comprises a second page operation;
the other command comprises a third command;
the other page operation comprises a third page operation; and
the method further comprises transmitting, prior to the first time period, a first command to perform a first page operation that enables the logic circuit to access the first data.

Example 19: The method of example 18, wherein:
the transmitting of the first command causes the memory device to activate a first row of the first bank that stores the first data; and
the transmitting of the second command causes the memory device to activate a second row of the second bank that stores the second data.

Example 20: The method of example 19, wherein the second row represents a same row of the second bank as the first row of the first bank.

What is claimed is:

1. A method performed by a memory device, the method comprising:
performing, during a first time period and using a logic circuit that is coupled to at least two banks, a first processing-in-memory computation using first data that had been read from a first bank of the at least two banks; and
performing, during the first time period, a page operation on a second bank of the at least two banks to enable the logic circuit to access second data that is stored within the second bank.

2. The method of claim 1, wherein:
the performing of the first processing-in-memory computation comprises receiving, from a memory controller of a host device, a processing-in-memory command that instructs the logic circuit to perform the first processing-in-memory computation;
the performing of the page operation comprises receiving, from the memory controller, a command that instructs the memory device to perform the page operation; and
a timing associated with the receiving of the processing-in-memory command and a timing associated with the receiving of the command causes the memory device to concurrently perform at least a portion of the first processing-in-memory computation and at least a portion of the page operation.

3. The method of claim 1, further comprising:
performing, during a second time period and using the logic circuit, a second processing-in-memory computation using the second data; and
performing, during the second time period, another page operation on the first bank to enable the logic circuit to access third data that is stored within the first bank.

4. The method of claim 3, wherein:
the page operation comprises a second page operation;
the other page operation comprises a third page operation; and
the method further comprises performing, prior to the first time period, a first page operation on the first bank to enable the logic circuit to access the first data.

5. The method of claim 4, wherein:
the performing of the first page operation on the first bank comprises activating a first row of the first bank that stores the first data; and
the performing of the second page operation on the second bank comprises activating a second row of the second bank that stores the second data.

6. The method of claim 5, wherein the first row and the second row comprise a same row of a corresponding bank.

7. The method of claim 5, wherein the performing of the third page operation on the first bank comprises:
precharging the first row of the first bank that stores the first data; and
activating a third row of the first bank that stores the third data.

8. The method of claim 1, wherein:
the first data and the second data comprise different sets of weights of a machine-learned model; and
the performing of the first processing-in-memory computation comprises performing, using a weight of the machine-learned model, at least one of a multiplication operation or an accumulation operation to implement a portion of the machine-learned model.

9. A memory device comprising:
a memory array comprising at least two banks;
a logic circuit coupled to the at least two banks and configured to perform, during a first time period, a first processing-in-memory computation using first data that had been read from a first bank of the at least two banks; and
read and write circuitry configured to perform, during the first time period, a page operation on a second bank of the at least two banks to enable the logic circuit to access second data that is stored within the second bank.

10. The memory device of claim 9, wherein:
the first bank is configured to be in an active state during the first time period; and
the second bank is configured to be in an idle state during the first time period.

11. The memory device of claim 10, wherein:
the logic circuit is configured to perform, during a second time period, a second processing-in-memory computation using the second data; and
the read and write circuitry is configured to perform, during the second time period, another page operation on the first bank to enable the logic circuit to access third data that is stored within the first bank.

12. The memory device of claim 11, wherein:
the first bank is configured to be in the idle state during the second time period; and
the second bank is configured to be in the active state during the second time period.

13. The memory device of claim 9, wherein:
the page operation comprises a second page operation;
the other page operation comprises a third page operation; and
the read and write circuitry is configured to perform, prior to the first time period, a first page operation on the first bank to enable the logic circuit to access the first data.

14. The memory device of claim 9, wherein:
the first data and the second data comprise different sets of weights of a machine-learned model; and
the logic circuit is configured to perform, using a weight of the machine-learned model, at least one of a multiplication operation or an accumulation operation to implement a portion of the machine-learned model.

15. A method performed by a memory controller, the method comprising:
transmitting, to a memory device capable of performing processing-in-memory, a processing-in-memory command to cause a logic circuit of the memory device to perform a first processing-in-memory computation using first data that had been read from a first bank of the memory device; and
transmitting, to the memory device, a command to perform a page operation that enables the logic circuit to access second data that is stored in a second bank of the memory device, the transmitting of the processing-in-memory command and the transmitting of the command causing the memory device to concurrently perform at least a portion of the first processing-in-memory computation and at least a portion of the page operation during a first time period.

16. The method of claim 15, wherein:
the first data and the second data comprise different sets of weights of a machine-learned model; and
the transmitting of the processing-in-memory command causes the logic circuit to perform, using a weight of the machine-learned model, at least one of a multiplication operation or an accumulation operation to implement a portion of the machine-learned model.

17. The method of claim 15, further comprising:
transmitting, to the memory device, a second processing-in-memory command to cause the logic circuit to perform a second processing-in-memory computation using the second data; and
transmitting, to the memory device, a second command to perform another page operation that enables the logic circuit to access third data that is stored in the first bank of the memory device, the transmitting of the second processing-in-memory command and the transmitting of the second command causing the memory device to concurrently perform at least a portion of the second processing-in-memory computation and at least a portion of the other page operation during a second time period.

18. The method of claim 17, wherein:
the command comprises a second command;
the page operation comprises a second page operation;
the other command comprises a third command;
the other page operation comprises a third page operation; and
the method further comprises transmitting, prior to the first time period, a first command to perform a first page operation that enables the logic circuit to access the first data.

19. The method of claim 18, wherein:
the transmitting of the first command causes the memory device to activate a first row of the first bank that stores the first data; and
the transmitting of the second command causes the memory device to activate a second row of the second bank that stores the second data.

20. The method of claim 19, wherein the second row represents a same row of the second bank as the first row of the first bank.
